(19) United States
(12) Patent Application Publication
(10) Pub. No.: US 2013/0323157 A1
(43) Pub. Date: Dec. 5, 2013

(54) Apparatus and Methods for the Synthesis of Graphene by Chemical Vapor Deposition

(71) Applicant: Xuesong Li, Wappingers Falls, NY (US)

(72) Inventor: Xuesong Li, Wappingers Falls, NY (US)

(21) Appl. No.: 13/484,310

(22) Filed: May 31, 2012

(51) Int. Cl. C23C 16/455; C23C 16/46; C01B 31/00; B82Y 30/00; B82Y 40/00

(52) U.S. Cl. 423/445 R; 118/715; 427/255.28; 977/843; 977/734

(57) ABSTRACT

An apparatus is provided for synthesizing a film on a substrate in a reactor that defines an outer reaction space. The apparatus comprises a vessel body and one or more vessel closures. The one or more vessel closures are adapted to be removably attached to the vessel body to form a reaction vessel therewith. The reaction vessel: i) comprises graphite; ii) defines an inner reaction space adapted to contain the substrate; iii) is adapted to be placed within the outer reaction space; and iv) is adapted to allow gas outside the reaction vessel to enter the inner reaction space.

### FIELD OF THE INVENTION

The present invention relates generally to apparatus and methods for material synthesis, and, more particularly, to apparatus and methods for the formation of graphene by chemical vapor deposition.

### BACKGROUND OF THE INVENTION

Graphene is a one-atom-thick sheet of sp²-hybridized carbon. Graphene is presently the target of intense study because of its many interesting and useful mechanical, optical, and electrical properties. Graphene, for example, can exhibit very high electron- and hole-mobilities and, as a result, may allow graphene-based electronic devices to display extremely high switching speeds. Moreover, because graphene is planar, it is compatible with many well-developed semiconductor processing techniques. Graphene may also be used as a membrane material in electromechanical systems, as a pressure sensor, and as a detector for chemical or biological molecules or cells.

Presently, very high quality graphene can be formed by the repeated mechanical exfoliation of graphite. Nevertheless, graphene produced by this method tends to be limited in size. As a result, researches have studied the chemical vapor deposition (CVD) of graphene as an alternative method of synthesis. U.S. Patent Publication No. 2011/0091647, to Colombo et al. and entitled “Graphene Synthesis by Chemical Vapor Deposition,” for example, teaches the CVD of graphene on metal and dielectric substrates using hydrogen and methane in a CVD tube reactor. Even so, there remain concerns that known CVD techniques, while being able to produce graphene films larger than those that can be formed by graphite exfoliation, may produce graphene films with qualities inferior to those found in exfoliated films. As a result, there is a continuing need for improved apparatus and methods for the formation of high quality graphene by CVD.

### SUMMARY OF THE INVENTION

Embodiments of the present invention address the above-identified need by providing apparatus and methods that facilitate the synthesis of high quality, large area graphene by CVD.

In accordance with an aspect of the invention, an apparatus is provided for synthesizing a film on a substrate in a reactor that defines an outer reaction space. The apparatus comprises a vessel body and one or more vessel closures. The one or more vessel closures are adapted to be removably attached to the vessel body to form a reaction vessel therewith. The reaction vessel: i) comprises graphite; ii) defines an inner reaction space adapted to contain the substrate; iii) is adapted to be placed within the outer reaction space; and iv) is adapted to allow gas outside the reaction vessel to enter the inner reaction space.

In accordance with another aspect of the invention, a film is synthesized on a substrate in a reactor that defines an outer reactor space. A vessel body and one or more closures are received. The one or more vessel closures are adapted to be removably attached to the vessel body to form a reaction vessel therewith with the reaction vessel so formed: i) comprising graphite; ii) defining an inner reaction space adapted to contain the substrate; iii) adapted to be placed within the outer reaction space; and iv) adapted to allow gas outside the reaction vessel to enter the inner reaction space. The reaction vessel is formed with the substrate disposed in the inner reaction space, and the reaction vessel and the substrate are then placed into the outer reaction space. Ultimately, the reaction vessel and substrate are heated.

Lastly, in accordance with another aspect of the invention, a product of manufacture comprises a film synthesized on a substrate in a reactor utilizing an apparatus. The reactor defines an outer reaction space. The apparatus, moreover, comprises a vessel body and one or more vessel closures. The one or more vessel closures are adapted to be removably attached to the vessel body to form a reaction vessel therewith. The reaction vessel: i) comprises graphite; ii) defines an inner reaction space adapted to contain the substrate; iii) is adapted to be placed within the outer reaction space; and iv) is adapted to allow gas outside the reaction vessel to enter the inner reaction space.

### BRIEF DESCRIPTION OF THE DRAWINGS

These and other features, aspects, and advantages of the present invention will become better understood with regard to the following description, appended claims, and accompanying drawings where:

FIG. 1A shows an end elevational view of a reaction vessel in accordance with a first illustrative embodiment of the invention;

FIG. 1B shows a sectional view of the FIG. 1A reaction vessel;

FIG. 2A shows a sectional view of a CVD system in accordance with an illustrative embodiment of the invention;

FIG. 2B shows a schematic diagram of an illustrative gas manifold for use with the FIG. 2 CVD system;

FIG. 2C shows a schematic diagram of an illustrative exhaust manifold for use with the FIG. 2 CVD system;

FIG. 3 shows a flow diagram of a method for growing graphene using the FIG. 2 CVD system in accordance with a first illustrative embodiment of the invention;

FIG. 4 shows a flow diagram of a method for growing graphene using the FIG. 2 CVD system in accordance with a second illustrative embodiment of the invention;

FIG. 5 shows a flow diagram of a method for growing graphene using the FIG. 2 CVD system in accordance with a third illustrative embodiment of the invention

FIG. 6A shows an end elevational view of a reaction vessel in accordance with a second illustrative embodiment of the invention; and

FIG. 6B shows a sectional view of the FIG. 6A reaction vessel.

### DETAILED DESCRIPTION OF THE INVENTION

The present invention will be described with reference to illustrative embodiments. For this reason, numerous modifications can be made to these embodiments and the results will still come within the scope of the invention. No limitations with respect to the specific embodiments described herein are intended or should be inferred.

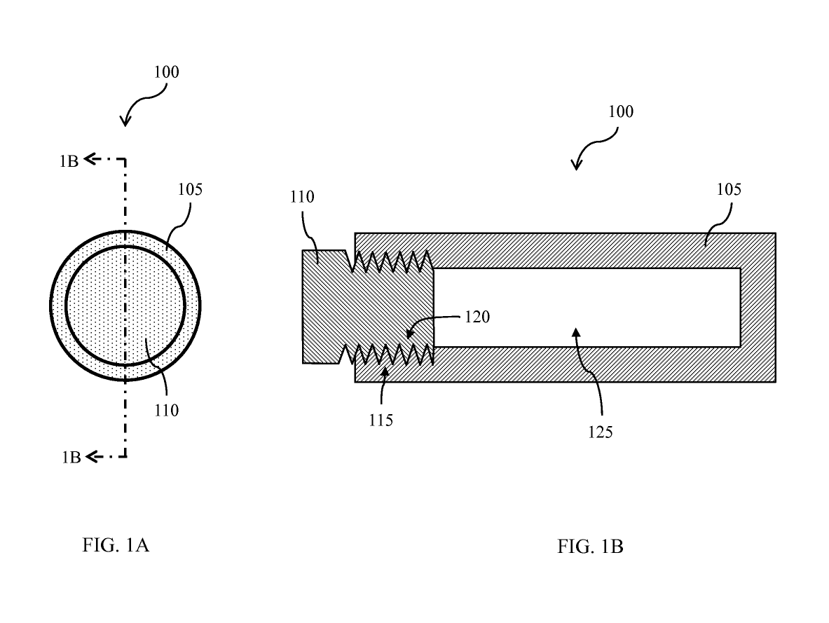

Illustrative embodiments of the invention, for example, utilize unique reaction vessel designs that, when caused to contain appropriate substrates and placed into the reaction spaces of CVD reactors, allow those CVD reactors to synthesize high quality graphene. FIG. 1A shows an end elevational view of a reaction vessel 100 in accordance with a first illustrative embodiment of the invention. FIG. 1B shows a sectional view of the FIG. 1A reaction vessel 100 cut along the plane indicated in FIG. 1A.

The reaction vessel 100 comprises a vessel body 105 and a vessel closure 110. In the present embodiment, the vessel body 105 defines a hollow cylindrical tube that is closed at one end. Opposite the closed end, the vessel body 105 defines female screw threads (i.e., internal screw threads) 115 that interlock with male screw threads (i.e., external screw threads) 120 on the vessel closure 110. The engagement of these screw threads 115, 120 allows the vessel closure 110 to be removably attached to the vessel body 105, as shown in FIG. 1B. Once so attached, the reaction vessel 100 defines an inner reaction space 125.

For purposes of growing graphene, the exemplary reaction vessel 100 is formed of graphite. For purposes of allowing the inner reaction space 125 to see reactive gases emanating from outside the reaction vessel 100, the screw threads 115, 120 are preferably sized so that the engagement between the vessel body 105 and the vessel closure 110 is somewhat “leaky.” Put another way, the interlocking screw threads 115, 120 are purposefully not so tightly coupled as to create a gas-tight seal. Instead, in accordance with aspects of the invention, the reaction vessel 100 is so adapted to allow gas outside the reaction vessel 100 to enter past where the vessel closure 110 attaches to the vessel body 105 and to ultimately enter into the inner reaction space 125. Once understood from the teachings herein, such graphite parts may be produced by conventional machining techniques that will already be familiar to one skilled in the machining arts (e.g., CNC milling).

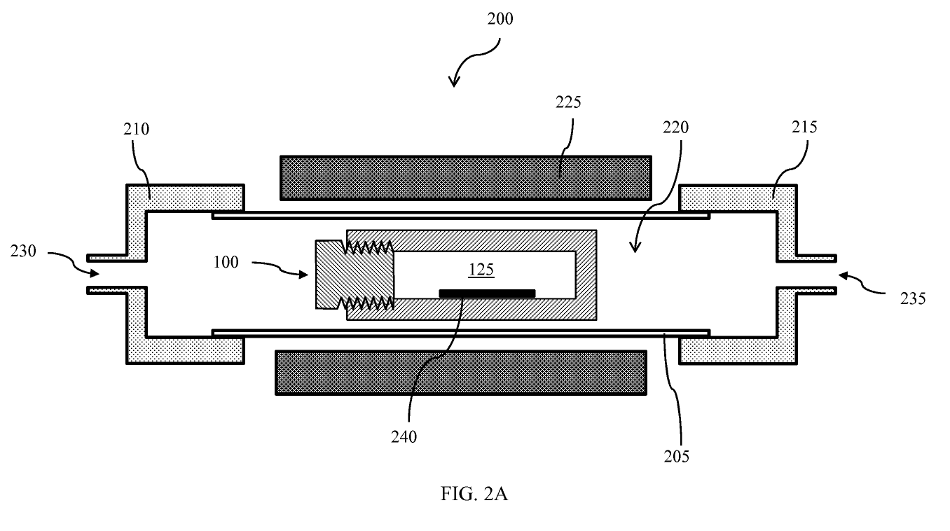

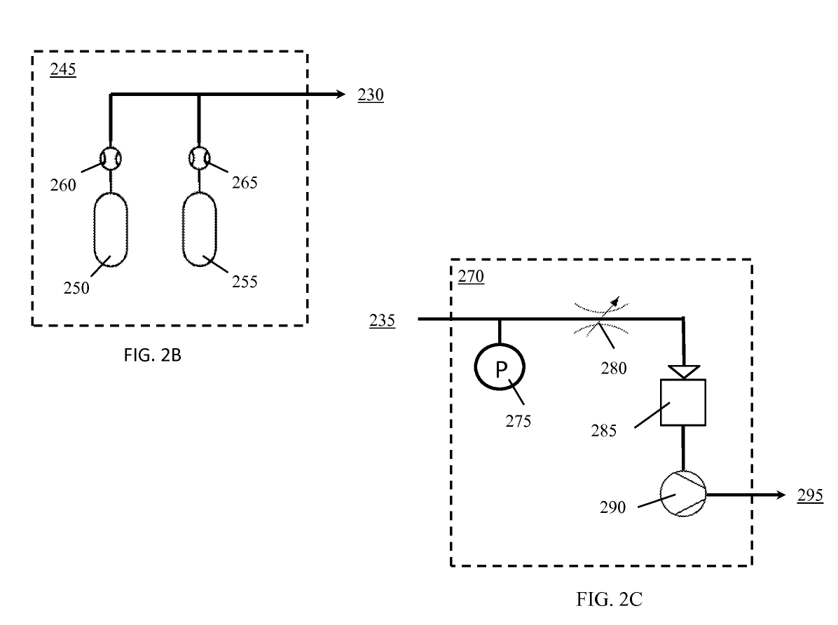

FIGS. 2A-2C show various aspects of a CVD system 200 in accordance with an illustrative embodiment of the invention. The CVD system 200 utilizes the reaction vessel 100 to synthesize films (e.g., graphene). FIG. 2A begins by showing a sectional view of the portion of the CVD system 200 where the synthesis is performed. In the present embodiment the CVD system 200 comprises several aspects of a conventional CVD tube furnace. Such CVD tube furnaces are described in many readily available publications, including, for example, A.C. Jones, Chemical Vapour Deposition: Precursors, Processes and Applications, Royal Society of Chemistry, 2009, which is hereby incorporated by reference herein. A transparent cylindrical reaction tube 205 (e.g., quartz or alumina) is suspended between a first support end 210 and a second support end 215 so as to define an outer reaction space 220. This outer reaction space 220, in turn, is surrounded by a furnace 225 capable of heating the outer reaction space 220. At the first support end 210, a gas inlet port 230 allows gases to be introduced into the outer reaction space 220. At the second support end 215, an exhaust gas port 235 allows gases in the outer reaction space 220 to be exhausted. The reaction vessel 100 sits within the outer reaction space 220. A substrate 240 is contained within the inner reaction space 125 of the reaction vessel 100.

In the present embodiment, the illustrative furnace 225 in the CVD system 200 comprises one or more resistive wire heating elements that are coiled around the outer reaction space 220. If desired, several distinct coils may be arranged along the longitudinal axis of the outer reaction space 220 to create separately-controllable heating zones. For temperature regulation, signals from thermocouples in the outer reaction space 220 may be fed back to a power source for the furnace 225 so as to maintain a predetermined temperature set point.

FIG. 2B shows a schematic diagram of an illustrative gas manifold 245 that can be used to introduce one or more reactive gases into the outer reaction space 220 of the CVD system 200 via the gas inlet port 230. In the present illustrative embodiment, the gas manifold 245 comprises two process gas sources 250, 255, although this particular number of process gas sources is largely arbitrary and a gas manifold with a fewer or a greater number of process gas sources would still fall within the scope of the invention. Each process gas source 250, 255 is in fluidic communication with a respective mass flow controller 260, 265 that acts to regulate the flow rate of the gas coming from that process gas source 250, 255 into the gas inlet port 230.

FIG. 2C, in turn, shows a schematic diagram of an exhaust manifold 270 that may form part of the CVD system 200. The exhaust manifold 270 is in fluidic communication with the outer reaction space 220 via the exhaust gas port 235. In the present illustrative embodiment, a gas flow, after leaving the outer reaction space 220 via the exhaust gas port 235, passes a pressure sensor 275 before entering a throttle valve 280. The pressure sensor 275 measures the pressure and, via a conventional electronic feedback mechanism, controls the opening of the throttle valve 280 to regulate a preset pressure in the outer reaction space 220. Once past the throttle valve 280, the gas flow first passes through a trap 285 (e.g., liquid nitrogen trap) and then is pumped by a rotary mechanical pump 290 before it is sent to an exhaust 295. A chemical scrubber may be provided if deemed necessary.

The inclusion of a reaction vessel 100 within a CVD system, as described above with reference to CVD system 200, is driven at least in part by the inventor's observation that the presence of water (H₂O) during graphene synthesis can adversely affect graphene quality. Water may, for example, etch graphene according to the following chemical reaction:

H₂O(g)+C(graphene)→CO(g)+H₂(g). (1)

It is understood by the inventor that this kind of etching ultimately results in point defects in the CVD graphene, thus at least partially explaining why CVD graphene may tend to not be equivalent in quality to graphene formed by the exfoliation of graphite.

Unfortunately, unwanted water can come from several sources in a CVD system such as the CVD system 200, and is therefore extremely difficult to avoid. It may, for example, be present as a background gas and/or as in impurity in one or more of the reactive gases. In addition, water may desorb from the wall of the cylindrical reaction tube 205 and/or desorb from the walls of the gas lines. Notably, in the illustrative CVD system 200, any unwanted water must first pass into the inner reaction space 125 of the reaction vessel 100 before it can reach the substrate 240 and harm the graphene being synthesized thereon. More particularly, to enter the inner reaction space 125 of the reaction vessel 100, any present water gas must first pass through the interlocking screw threads 115, 120 of the vessel body 105 and the vessel closure 110. In so doing, the water is thereby exposed to a relatively large surface area of hot graphite.

In a manner similar to the manner in which water reacts with graphene (chemical reaction (1)), water also reacts with hot graphite according to the chemical reaction:

H₂O(g)+C(graphite)→CO(g)+H₂(g). (2)

Such a chemical reaction is regularly used, for example, to gasify hot coal by water vapor. As a result of chemical reaction (2), any unwanted water is substantially depleted while passing through the interlocking screw threads 115, 120 of the reaction vessel 100 before arriving at the substrate 240. At the same time, the evolved hydrogen (H₂) gas further reacts with the hot graphite of the reaction vessel 100 by the chemical reaction:

2H₂(g)+C(graphite)→CH₄(g), (3)

a reaction also seen in coal gasification. Ultimately, the evolved methane (CH₄) gas reacts with the hot substrate 240 by the chemical reaction:

CH₄(g)+substrate→graphene. (4)

Thus, through the sequence of the chemical reactions (2), (3), and (4), the unwanted water in combination with the reaction vessel 100 actually results in graphene synthesis, rather than the production of defects in the graphene.

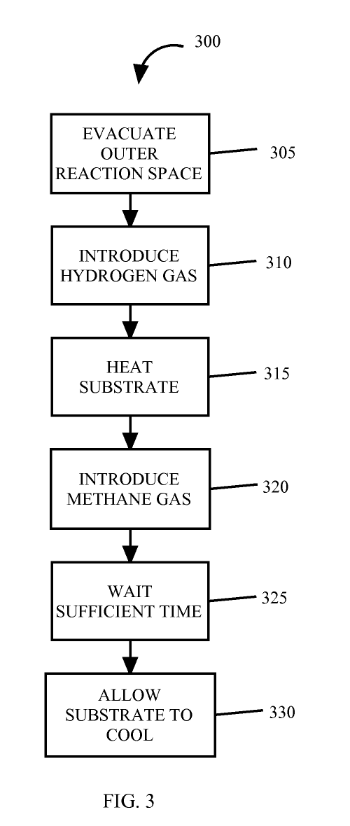

FIGS. 3-5 go on to show flow charts of exemplary methods for utilizing the CVD system 200 to grow graphene on the substrate 240 contained within the inner reaction space 125 of the reaction vessel 100, in accordance with embodiments of the invention. Each of these methods relies on the chemical reaction (2) occurring at the interlocking screw threads 115, 120 of the reaction vessel 100 to deplete any unwanted water before it can adversely affect graphene growth, as well as the chemical reactions (3) and (4) to ultimately grow the graphene on the substrate 240. In the present embodiment, the substrate 240 may comprise a metal (e.g, copper, copper and nickel, copper and cobalt, and copper and ruthenium) or a dielectric (e.g., zirconium dioxide, hafnium oxide, boron nitride, and aluminum oxide). Thin copper foil has been demonstrated to be a particularly good substrate 240 for graphene synthesis by CVD and is therefore preferred.

Now referring to FIG. 3, a method 300 for forming graphene starts in the CVD system 200 by evacuating the outer reaction space 220 (which contains the reaction vessel 100 and the substrate 240) by pumping the outer reaction space 220 down to the extent allowed by the exhaust manifold 270, as indicated in step 305. Subsequently, in step 310, a flow of hydrogen gas is introduced into the outer reaction space 220 while maintaining a predetermined pressure utilizing the gas manifold in combination with the exhaust manifold 270. The flow rate of the hydrogen gas may be set, for example, between about one standard cubic centimeters per second (sccm) and about 1,000 sccm, and the pressure may be set between about 20 mTorr and about 100 mTorr. Nevertheless, like all specified flow, pressure, temperature, and time values related herein with reference to FIGS. 3-5, these particular values are merely illustrative, and alternative values are contemplated and would also come within the scope of the invention.

Subsequently, in step 315, the furnace 225 is utilized to heat the elements within the outer reaction space 220. The elements within the outer reaction space 220 may, for example, be heated to between about 600° C. (degrees Celsius) and about 1,400° C. After waiting sufficient time to allow things to equilibrate, methane gas is then introduced into the outer reaction space 220, as indicated in step 320. Methane flow rate may be, for example, between about 0.01 sccm and about 1,000 sccm, while the pressure is maintained in the outer reaction space 220 such that the partial pressure of methane is between about 0.1 mTorr and about 10 Torr.

With the methane flowing in this manner, sufficient time is then allowed for the graphene to grow on the substrate 240 within the reaction vessel 100, as indicated in step 325. Periods of between about 0.1 minutes and about 100 minutes may be sufficient. Once sufficient time has been allocated, the methane and hydrogen gas flows are shut off and the elements within the outer reaction space 220 are allowed to cool to room temperature, as indicated in step 330.

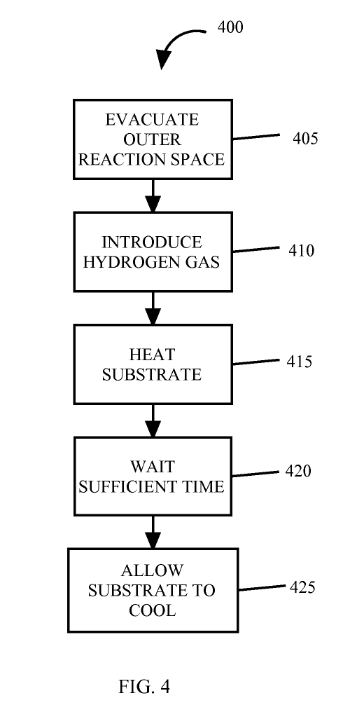

FIG. 4 shows aspects of an alternative graphene deposition method 400 for the CVD system 200. The method 400 differs from the method 300 in that only hydrogen gas (not methane) is intentionally introduced into the outer reaction space 220 via the gas manifold 245. The hydrogen gas reacts with the graphite reaction vessel 100 to produce methane by the chemical reaction (3). At the same time, any water is removed by the chemical reaction (2) before it can adversely affect the graphene.

In step 405 of the illustrative method 400, the outer reaction space 220 is evacuated, and then, in step 410, hydrogen gas is introduced by the gas manifold (e.g., hydrogen flow rate between about one sccm and about 1,000 sccm; and pressure between about 20 mTorr and about 100 mTorr). Subsequently, in step 415, the furnace 225 is utilized to heat the elements within the outer reaction space 220 (e.g., to between about 600° C. and about 1,400° C.). Sufficient time (e.g., about 0.1 minutes to about 100 minutes) is then allowed in step 420 for the graphene to grow on the substrate 240 within the reaction vessel 100. Once sufficient time has been allowed, the hydrogen gas flow is shut off and the elements within the outer reaction space 220 are allowed to cool to room temperature, as indicated in step 425

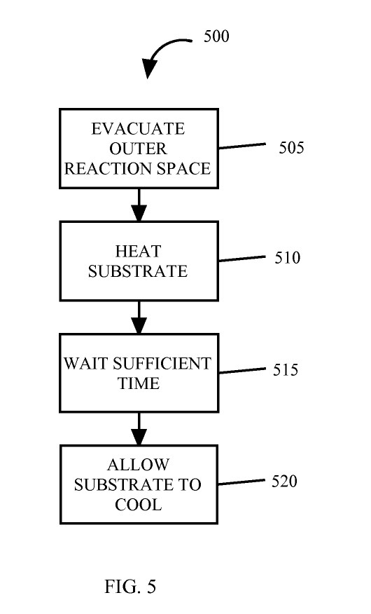

Lastly, aspects of even one more alternative method 500 for forming graphene in the CVD system 200 are shown in FIG. 5. In this case, the method 500 differs from both the method 300 and the method 400 in that no gases at all are intentionally introduced into the outer reaction space 220 utilizing the gas manifold 245. Instead, the method 500 relies on only residual water to form methane and ultimately graphene via chemical reactions (2), (3), and (4).

In step 505 of the illustrative method 500, the outer reaction space 220 is evacuated, and, in step 510, the furnace 225 is utilized to heat the elements within the outer reaction space 220 (e.g., to between about 600° C. and about 1,400° C.). Sufficient time (e.g., about 0.1 minutes to about 100 minutes) is then allowed in step 515 for the graphene to grow on the substrate 240 within the reaction vessel 100. After the wait, the elements within the outer reaction space 220 are allowed to cool to room temperature, as indicated in step 520.

It should again be emphasized that the above-described apparatus and method embodiments of the invention are intended to be illustrative only. Other embodiments can use different types and arrangements of elements for implementing the described functionality. These numerous alternative embodiments within the scope of the appended claims will be apparent to one skilled in the art.

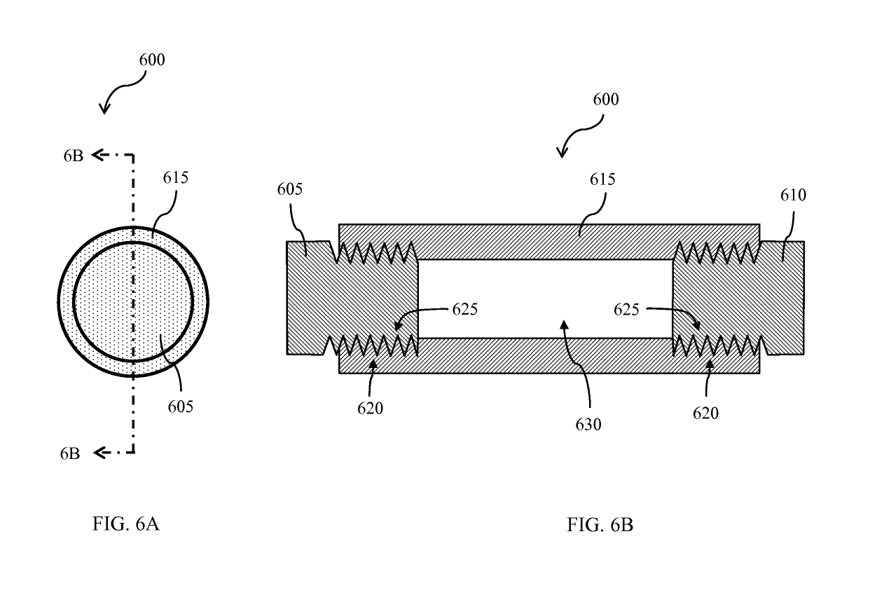

FIGS. 6A and 6B, for example, show aspects of an alternative reaction vessel 600 in accordance with a second illustrative embodiment of the invention. FIG. 6A shows an end elevational view of the reaction vessel 600, while FIG. 6B shows a sectional view cut along the plane indicated in FIG. 6A. Like the reaction vessel 100, the alternative reaction vessel 600 may be used in the CVD system 200 and may be used in conjunction with the methods 300, 400, 500. However, unlike the reaction vessel 100, the reaction vessel 600 utilizes two vessel closures 605, 610 rather than just one. To utilize the two vessel closures 605, 610, a vessel body 615 defines a hollow cylindrical tube with female screw threads 620 at opposing ends. Male screw threads 625 on each of the vessel closures allow the two vessel closures 605, 610 to be removably attached to the opposing ends of the vessel body 615 in the manner shown in FIG. 6B. Attached in this manner, the reaction vessel 600 defines an inner reaction space 630.

While screw threads were used to removably engage the vessel closures to their respective vessel bodies in the embodiments set forth above (i.e., reaction vessels 100, 600), several other forms of removable attachment means are also contemplated and would come within the scope of the invention. In one or more embodiments, for example, a vessel closure may be formed with a truncated cylindrical or conical extension that may be inserted into an inversely shaped portion of a vessel body, thereby allowing the vessel closure to act as a kind of stopper or bung. In the case of reaction vessel designs based on both screw threads and stopper-like arrangements, if the passage of gas from outside the reaction vessel into the reaction vessel is deemed insufficient, it may be enhanced as necessary by forming small channels into the features of the vessel closure(s) and vessel body where they engage one another to form passages for the gas.

In even one or more alternative embodiments, moreover, a CVD system may utilize a heating means substantially different from the resistive heating elements described above with reference to the furnace 225. Alternative embodiments may, for example, utilize high-intensity radiation lamps which are commonly utilized in conventional “cold wall” CVD reactors.

All the features disclosed herein may be replaced by alternative features serving the same, equivalent, or similar purposes, unless expressly stated otherwise. Thus, unless expressly stated otherwise, each feature disclosed is one example only of a generic series of equivalent or similar features.

Any element in a claim that does not explicitly state “means for” performing a specified function or “step for” performing a specified function is not to be interpreted as a “means for” or “step for” clause as specified in 35 U.S.C. §112, ¶6. In particular, the use of “step of” in the claims herein is not intended to invoke the provisions of 35 U.S.C. §112, ¶6.

What is claimed is:

1. An apparatus for synthesizing a film on a substrate in a reactor, the reactor defining an outer reaction space, and the apparatus comprising:
a vessel body; and
one or more vessel closures, the one or more vessel closures adapted to be removably attached to the vessel body to form a reaction vessel therewith, the reaction vessel: i) comprising graphite; ii) defining an inner reaction space adapted to contain the substrate; iii) adapted to be placed within the outer reaction space; and iv) adapted to allow gas outside the reaction vessel to enter the inner reaction space.

2. The apparatus of claim 1, wherein the reactor is a chemical vapor deposition reactor.

3. The apparatus of claim 1, wherein the reactor is a chemical vapor deposition tube furnace.

4. The apparatus of claim 1, wherein the film comprises graphene.

5. The apparatus of claim 1, wherein an exposed surface of the substrate comprises a metal.

6. The apparatus of claim 5, wherein the exposed surface comprises copper.

7. The apparatus of claim 1, wherein an exposed surface of the substrate comprises a dielectric.

8. The apparatus of claim 1, wherein each of the vessel body and the one or more vessel closures comprises graphite.

9. The apparatus of claim 1, wherein the vessel body defines a hollow cylindrical tube.

10. The apparatus of claim 1, wherein the one or more vessel closures consists of two vessel closures.

11. The apparatus of claim 1, wherein each of the one or more vessel closures is adapted to screwably attach to the vessel body.

12. The apparatus of claim 1, wherein the vessel body defines female screw threads.

13. The apparatus of claim 1, wherein each of the one or more vessel closures defines respective male screw threads.

14. The apparatus of claim 1, wherein the reaction vessel is adapted to allow the gas outside the reaction vessel to enter the inner reaction space where the one or more vessel closures removably attach to the vessel body.

15. A method for synthesizing a film on a substrate in a reactor, the reactor defining an outer reaction space, and the method comprising the steps of:
receiving a vessel body;
receiving one or more vessel closures, the one or more vessel closures adapted to be removably attached to the vessel body to form a reaction vessel therewith, the reaction vessel: i) comprising graphite; ii) defining an inner reaction space adapted to contain the substrate; iii) adapted to be placed within the outer reaction space; and iv) adapted to allow gas outside the reaction vessel to enter the inner reaction space;
forming the reaction vessel with the substrate disposed in the inner reaction space;
placing the reaction vessel and the substrate into the outer reaction space; and
heating the reaction vessel and the substrate.

16. The method of claim 15, further comprising the step of introducing one or more reactive gases into the outer reaction space.

17. The method of claim 15, wherein a constituent of the reaction vessel chemically reacts with water so as to remove the water.

18. The method of claim 15, further comprising the step of introducing at least one of hydrogen and methane into the outer reaction space.

19. The method of claim 15, wherein the film is synthesized without flowing a reactive gas into the outer reaction space.

20. A product of manufacture, the product of manufacture comprising a film synthesized on a substrate in a reactor utilizing an apparatus, the reactor defining an outer reaction space, and the apparatus comprising:
a vessel body; and
one or more vessel closures, the one or more vessel closures adapted to be removably attached to the vessel body to form a reaction vessel therewith, the reaction vessel: i) comprising graphite; ii) defining an inner reaction space adapted to contain the substrate; iii) adapted to be placed within the outer reaction space; and iv) adapted to allow gas outside the reaction vessel to enter the inner reaction space.
